(19) United States
(12) Patent Application Publication
(10) Pub. No.: US 2019/0136371 A1
(43) Pub. Date: May 9, 2019

(54) MOLYBDENUM SUBSTRATE WITH AN AMORPHOUS CHEMICAL VAPOR DEPOSITION COATING

(71) Applicant: SILCOTEK CORP., Bellefonte, PA (US)

(72) Inventor: Jesse BISCHOF, State College, PA (US)

(21) Appl. No.: 16/181,512

(22) Filed: Nov. 6, 2018

Related U.S. Application Data
(60) Provisional application No. 62/581,972, filed on Nov. 6, 2017.

(51) Int. Cl. C23C 16/24; C23C 16/44; C23C 16/02; C23C 16/56

(52) U.S. Cl. CPC C23C 16/24; C23C 16/56; C23C 16/0227; C23C 16/44

(57) ABSTRACT

Article having a molybdenum substrate and an amorphous chemical vapor deposition coating on the molybdenum substrate, processes of using the articles, and processes of producing the articles are disclosed. The articles include a molybdenum substrate and an amorphous chemical vapor deposition coating on the molybdenum substrate. The amorphous chemical vapor deposition coating includes silicon. The processes of using the article include exposing the article to temperatures of greater than 1,200° C. The processes of producing the article include positioning the molybdenum substrate, and applying the amorphous chemical vapor deposition coating on the molybdenum substrate through thermal chemical vapor deposition.

### PRIORITY

This application is a United States non-provisional patent application claiming priority and benefit of U.S. provisional patent application No. 62/581,972, filed Nov. 6, 2017 and titled “MOLYBDENUM SUBSTRATE WITH AN AMORPHOUS CHEMICAL VAPOR DEPOSITION COATING,” the entirety of which is incorporated by reference.

### FIELD OF THE INVENTION

The present invention is directed to molybdenum substrates with an amorphous chemical vapor deposition coating. More particularly, the present invention is directed to an article having a molybdenum substrate and an amorphous chemical vapor deposition coating on the molybdenum substrate, a process of using the article, and a process of producing the article.

### BACKGROUND OF THE INVENTION

Molybdenum is a known material with desirable properties. The coefficient of thermal expansion is compatible with many uses that differ from other metals, such as stainless steel. Molybdenum has one of the lowest coefficients of thermal expansion of any commercially-used metals. Molybdenum has other desirable properties: it is hard, inert, and generally requires little or no treatment to be used in a variety of processes.

Coating molybdenum can be problematic. Certain properties of molybdenum are not realized when a coating covers the molybdenum. For example, a soft coating that easily scratches does not allow the hardness of molybdenum to be useful. In addition, coating molybdenum present challenges that can be detrimental. For example, mismatch of coefficients of thermal expansion can cause incompatibility illustrated by delamination.

In US Patent Publication No. 2009/0197075, which is hereby incorporated by reference in its entirety, a molybdenum base material is coated with a molybdenum disilicide to provide a transition of coefficients of thermal expansion prior to an exterior coating of alumina. Similar techniques are applied to molybdenum base materials further including boron or silicon. In such techniques, however, temperatures are maintained below 1,200° C. to avoid over-heating to 1,500° C., which can result in re-crystallization of molybdenum.

A coating for molybdenum substrates, a process of using coated molybdenum substrate, and a process of producing the coated molybdenum substrate that do not suffer from one of the above drawbacks and/or that show further improvements would be desirable in the art.

### BRIEF DESCRIPTION OF THE INVENTION

In an embodiment, an article includes a molybdenum substrate and an amorphous chemical vapor deposition coating on the molybdenum substrate. The amorphous chemical vapor deposition coating includes silicon.

In another embodiment, a process of using an article includes providing the article and exposing the article to temperatures of greater than 1,200° C. The article includes a molybdenum substrate, and an amorphous chemical vapor deposition coating on the molybdenum substrate, wherein the amorphous chemical vapor deposition coating includes silicon.

In another embodiment, a process of producing an article includes positioning a molybdenum substrate, and applying an amorphous chemical vapor deposition coating on the molybdenum substrate through thermal chemical vapor deposition, wherein the amorphous chemical vapor deposition coating includes silicon.

Other features and advantages of the present invention will be apparent from the following more detailed description, taken in conjunction with the accompanying drawing which illustrates, by way of example, the principles of the invention.

### BRIEF DESCRIPTION OF THE DRAWINGS

FIG. 1 is a schematic view of an article having a molybdenum substrate and an amorphous chemical vapor deposition coating on the molybdenum substrate chemical vapor deposition coated article, according to an embodiment of the disclosure.

Wherever possible, the same reference numbers will be used throughout the drawings to represent the same parts.

### DETAILED DESCRIPTION OF THE INVENTION

Provided are an article having a molybdenum substrate and an amorphous chemical vapor deposition coating on the molybdenum substrate, a process of using the article, and a process of producing the article. Embodiments of the present disclosure, for example, in comparison to concepts failing to include one or more of the features disclosed herein, increase consistency/repeatability of treatment, allow use of thermal processing cycles after cleaning and/or treatment, remove additional residual materials and/or contaminants (for example, residual treatment and/or cleaning materials), reduce or eliminate effects of residual materials thermally processed, increase inertness, increase resistance to sulfur adsorption, homogenize aesthetics, modify microstructure, modify optical properties, modify porosity, modify corrosion resistance, modify gloss, modify surface features, permit more efficient production of treatments, permit treatment of a wide range of geometries (for example, narrow channels/tubes, three-dimensionally complex geometries, and/or hidden or non-line-of-site geometries, such as, in needles, tubes, probes, fixtures, complex planar and/or non-planar geometry articles, simple non-planar and/or planar geometry articles, and combinations thereof), reduce or eliminate defects/microporosity, permit treatment of a bulk of articles, are capable or being used in or replacing components that are used in industries traditionally believed to be too sensitive for processes that are not flow-through processes (for example, based upon compositional purity, presence of contaminants, thickness uniformity, and/or amount of gas phase nucleation embedded within), have coefficients of thermal expansion that do not result in delamination when exposed to elevated temperatures, allow materials to be used as a substrate that would otherwise produce an electrical arc in a plasma environment, or permit a combination thereof.

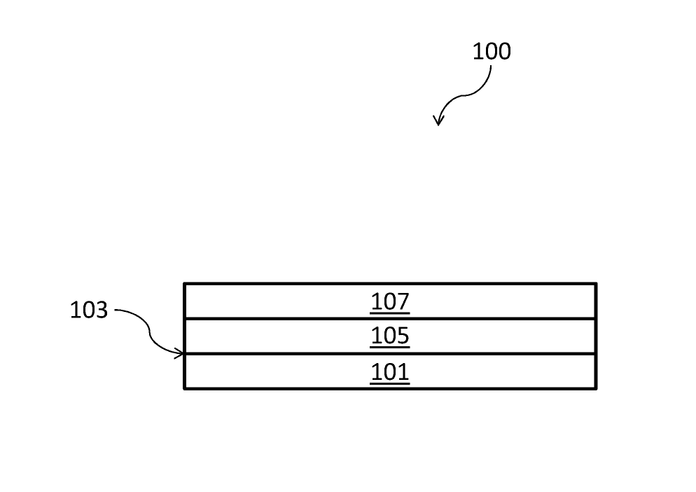

Referring to FIG. 1, in one embodiment, an article 100 includes a molybdenum substrate 101, a surface 103, an oxide layer 105, and an amorphous chemical vapor deposition coating 107. Suitable components capable of being produced into the article 100 include, but are not limited to, fittings (for example, unions, connectors, adaptors, other connections between two or more pieces of tubing, for example, capable of making a leak-free or substantially leak-free seal), compression fittings (including ferrules, such as, a front and back ferrule), tubing (for example, coiled tubing, tubing sections such as used to connect a sampling apparatus, pre-bent tubing, straight tubing, loose wound tubing, tightly bound tubing, and/or flexible tubing, whether consisting of the interior being treated or including the interior and the exterior being treated), valves (such as, gas sampling, liquid sampling, transfer, shut-off, or check valves, for example, including a rupture disc, stem, poppet, rotor, multi-position configuration, able to handle vacuum or pressure, a handle or stem for a knob, ball-stem features, ball valve features, check valve features, springs, multiple bodies, seals, needle valve features, packing washers, and/or stems), quick-connects, sample cylinders, regulators and/or flow-controllers (for example, including o-rings, seals, and/or diaphragms), injection ports (for example, for gas chromatographs), in-line filters (for example, having springs, sintered metal filters, mesh screens, and/or weldments), glass liners, gas chromatograph components, liquid chromatography components, components associated with vacuum systems and chambers, components associated with analytical systems, sample probes, control probes, downhole sampling containers, drilled and/or machined block components, manifolds, particles, powders, or a combination thereof.

In one embodiment, the article 100 has a surface 103 having a non-planar geometry. Exemplary non-planar geometries include having features selected from the group consisting of channels, curves, threading, vanes, protrusions, cavities, junctions, mating interfaces, and combinations thereof. The surface 103 is capable of being coated with the amorphous chemical vapor deposition coating 107 in one or more single continuous layers extending over a plurality of regions incapable of being coated by a line-of-site technique. For example, in one embodiment, the surface 103 extends from the interior and to the exterior of a tube and is capable of having a single layer of the amorphous chemical vapor deposition coating 107 that extends from the interior to the exterior without physical microstructural segregation. In contrast, techniques that rely upon multiple layers to cover such regions include distinctive borders between the layers. In further embodiments, the oxide layer 105 is between the surface 103 and the amorphous chemical vapor deposition coating 107.

The composition of the molybdenum substrate 101 corresponds with the desired applications. Suitable compositions include, but are not limited to, having greater than 50% molybdenum, having greater than 80% molybdenum, having greater than 90% molybdenum, having greater than 99% molybdenum, or any suitable combination, sub-combination, range, or sub-range therein.

Suitable compositions of the treatment include having, nitric acid, citric acid, sodium dichromate, oxalic acid, a solubilizer, a chelating agent, a surfactant, an anti-foaming agent, or a combination thereof.

Suitable durations of the treatment (independent of any subsequent rinse) include, but are not limited to, a minimum of 4 minutes, a minimum of 10 minutes, a minimum of 20 minutes, a minimum of 30 minutes, between 4 minutes and 30 minutes, between 4 minutes and 20 minutes, between 4 minutes and 10 minutes, between 10 minutes and 30 minutes, between 10 minutes and 20 minutes, between 4 minutes and 90 minutes, between 10 minutes and 90 minutes, between 20 minutes and 90 minutes, between 40 minutes and 90 minutes, between 70 minutes and 90 minutes, at least 100 minutes, or any suitable combination, sub-combination, range, or sub-range therein.

Suitable temperatures for the treatment include, but are not limited to, between 20 and 80° C., between 20 and 70° C., between 20 and 60° C., between 20 and 50° C., between 20 and 30° C., between 50 and 55° C., between 50 and 60° C., between 60 and 70° C., between 60 and 80° C., between 70 and 80° C., or any suitable combination, sub-combination, range, or sub-range therein.

In a further embodiment, the treatment includes a rinse, for example, immediately after removal from a solution and/or the additional components of the treatment. The surface 103 is rinsed using stagnant, countercurrent, or spray washes, singly or in combination, with or without a separate chemical treatment for neutralization, followed by a final rinse using water (such as deionized water) to achieve a total solids content of less than 200 ppm. In one embodiment, the neutralization includes an immersion for at least 30 minutes in a solution of at least 5% NaOH (by weight) within a temperature range of between 70 and 80 degrees Celsius.

The oxide layer 105 is on the surface 103, extends into the surface 103, or extends through the surface 103 into or bordering the molybdenum substrate 101. The oxide layer 105 is formed by oxidizing the surface 103 and/or the molybdenum substrate 101. In one embodiment, the oxidizing is performed within an enclosed vessel. The enclosed vessel has any dimensions or geometry that allows suitable temperature and the pressures. In one embodiment, the dimensions for the enclosed vessel include, but are not limited to, having a minimum width of greater than 5 cm, greater than 10 cm, greater than 20 cm, greater than 30 cm, greater than 100 cm, greater than 300 cm, greater than 1,000 cm, between 10 cm and 100 cm, between 100 cm and 300 cm, between 100 cm and 1,000 cm, between 300 cm and 1,000 cm, any other minimum width capable of uniform or substantially uniform heating, or any suitable combination, sub-combination, range, or sub-range therein. Suitable volumes for the enclosed vessel include, but are not limited to, at least 1,000 cm³, greater than 3,000 cm³, greater than 5,000 cm³, greater than 10,000 cm³, greater than 20,000 cm³, between 3,000 cm³ and 5,000 cm³, between 5,000 cm³ and 10,000 cm³, between 5,000 cm³ and 20,000 cm³, between 10,000 cm³ and 20,000 cm³, any other volumes capable of uniform or substantially uniform heating, or any suitable combination, sub-combination, range, or sub-range therein.

In one embodiment, an oxidant is introduced to the enclosed vessel. Suitable oxidants include, but are not limited to, water (alone, with zero air, or with an inert gas), oxygen (for example, at a concentration, by weight, of at least 50%), air (for example, alone, not alone, and/or as zero air), nitrous oxide, ozone, peroxide, or a combination thereof. As used herein, the term “zero air” refers to atmospheric air having less than 0.1 ppm total hydrocarbons. The term “air” generally refers to a gaseous fluid, by weight, of mostly nitrogen, with the oxygen being the second highest concentration species within. For example, in one embodiment, the nitrogen is present at a concentration, by weight, of at least 70% (for example, between 75% and 76%) and oxygen is present at a concentration, by weight, of at least 20% (for example, between 23% and 24%).

Suitable thicknesses of the oxide layer 105 include, but are not limited to, greater than 3 nanometers, greater than 5 nanometers, between 3 nanometers and 5 nanometers, between 3 nanometers and 10 nanometers, greater than 20 nanometers, between 3 nanometers and 20 nanometers, between 5 nanometers and 10 nanometers, between 5 nanometers and 20 nanometers, or any suitable combination, sub-combination, range, or sub-range therein. Alternatively, in one embodiment, the oxide layer has a thickness of less than 1.5 nanometers. As used herein, the term “thickness,” as it relates to the oxide layer 105, is the region having non-native oxygen, for example, proximal to the molybdenum substrate 101 being at an atomic concentration being greater than 5% of oxygen concentration of the molybdenum substrate 101 and proximal to the amorphous chemical vapor deposition 107 having a higher atomic concentration of oxygen compared to silicon.

The amorphous chemical vapor deposition coating 107 is on the oxide layer 105 and/or diffuses into the oxide layer 105. The amorphous chemical vapor deposition coating 107 is produced on all exposed surfaces. As used herein, the term “exposed,” with regard to “exposed surfaces,” refers to any surface that is in contact with gas during the process, and is not limited to line-of-site surfaces or surfaces proximal to line-of-site directions as are seen in flow-through chemical vapor deposition processes that do not have an enclosed vessel. As will be appreciated by those skilled in the art, the article 100 is capable of being incorporated into a larger component or system (not shown).

The amorphous chemical vapor deposition coating 107 is produced, for example, thereby providing features and properties unique to being produced through the thermal chemical vapor deposition process, according to the disclosure, which is a static process using the enclosed vessel contrasted to flowable chemical vapor deposition that has concurrent flow of a precursor into and out of a chamber. As used herein, the phrase “thermal chemical vapor deposition” refers to a reaction and/or decomposition of one or more gases, for example, in a starved reactor configuration, and is distinguishable from plasma-assisted chemical vapor deposition, radical-initiated chemical vapor deposition, and/or catalyst-assisted chemical vapor deposition, sputtering, atomic layer deposition (which is limited to a monolayer molecular deposition per cycle in contrast being capable of more than one layer of molecular deposition), and/or epitaxial growth (for example, growth at greater than 700° C.). In one embodiment, the amorphous chemical vapor deposition coating 107 is on the article 100 on regions that are unable to be coated through line-of-sight techniques.

In one embodiment, one or a plurality of articles having the oxide layer 105 are positioned within the enclosed vessel. In further embodiments, the positioning is manually with the articles being arranged in a vertical (stacked) orientation separated by supports (and thus obstructed from line-of-sight), arranged laterally or perpendicular to gravity (for example, with all or most openings being perpendicular to gravity), arranged in an overlapping manner that reduces the amount of volume available for gas phase nucleation, positioned in a fixture corresponding with the geometry of the articles, or a combination thereof.

After the positioning, the process includes introducing a precursor fluid (for example, liquid or gas, but not plasma) to the enclosed vessel, for example, as a first aliquot, then soaking the oxide layer 105 at a temperature above the thermal decomposition temperature of the precursor fluid to produce the amorphous chemical vapor deposition coating 107. In one embodiment, the process further includes repeating the introducing of the precursor fluid, for example, as a second aliquot, or introducing a different precursor fluid, to produce additional layers. The soaking is at a temperature above the thermal decomposition temperature of the precursor fluid or the different precursor fluid.

Suitable thicknesses of the amorphous chemical vapor deposition coating 107 include, but are not limited to, between 100 nanometers and 10,000 nanometers, between 100 nanometers and 1,000 nanometers, between 100 nanometers and 800 nanometers, between 200 nanometers and 600 nanometers, between 200 nanometers and 10,000 nanometers, between 500 nanometers and 3,000 nanometers, between 500 nanometers and 2,000 nanometers, between 500 nanometers and 1,000 nanometers, between 1,000 nanometers and 2,000 nanometers, between 1,000 nanometers and 1,500 nanometers, between 1,500 nanometers and 2,000 nanometers, 800 nanometers, 1,200 nanometers, 1,600 nanometers, 1,900 nanometers, or any suitable combination, sub-combination, range, or sub-range therein.

The amorphous chemical vapor deposition coating 107 is formed by one or more of the following fluids: silane, silane and ethylene, silane and an oxidizer, dimethylsilane, dimethylsilane and an oxidizer, trimethylsilane, trimethylsilane and an oxidizer, dialkylsilyl dihydride, alkylsilyl trihydride, non-pyrophoric species (for example, dialkylsilyl dihydride and/or alkylsilyl trihydride), thermally-reacted material (for example, carbosilane and/or carboxysilane, such as, amorphous carbosilane and/or amorphous carboxysilane), species capable of a recombination of carbosilyl (disilyl or trisilyl fragments), methyltrimethoxysilane, methyltriethoxysilane, dimethyldimethoxysilane, dimethyldiethoxysilane trimethylmethoxysilane, trimethylethoxysilane, ammonia, hydrazine, trisilylamine, Bis(tertiary-butylamino)silane, 1,2-bis(dimethylamino)tetramethyldisilane, dichlorosilane, hexachlorodisilane), organofluorotrialkoxysilane, organofluorosilylhydride, organofluoro silyl, fluorinated alkoxysilane, fluoroalkylsilane, fluorosilane, tridecafluoro 1,1,2,2-tetrahydrooctylsilane, (tridecafluoro-1,1,2,2-tetrahydrooctyl) triethoxysilane, triethoxy (3,3,4,4,5,5,6,6,7,7,8,8,8-tridecafluoro-1-octyl) silane, (perfluorohexylethyl) triethoxysilane, silane (3,3,4,4,5,5,6,6,7,7,8,8,9,9,10,10,10-heptadecafluorodecyl) trimethoxy-, or a combination thereof.

The amorphous chemical vapor deposition coating 107 of the article 100 includes chemical constituents based upon the decomposition and/or heating of the fluid. Suitable chemical constituents include, carbon, oxygen, silicon (for example, amorphous silicon), fluorine, nitrogen, hydrogen, and combinations thereof. In some embodiments, the amorphous chemical vapor deposition coating 107 includes nitrogen, is devoid of compositional ring structures, includes oxygen (for example, at a greater concentration, by weight, than silicon) or alternatively is devoid or substantially devoid of oxygen (substantially devoid being a concentration of less than 0.1%, by weight), includes a lattice of voids from thermal removal of carbonaceous material, is devoid of molybdenum, or a combination thereof.

Suitable concentrations of thermally-reactive gas used in the thermal chemical vapor deposition, by volume, are between 10% and 20%, between 10% and 15%, between 12% and 14%, between 10% and 100%, between 30% and 70%, between 50% and 80%, between 70% and 100%, between 80% and 90%, between 84% and 86%, or any suitable combination, sub-combination, range, or sub-range therein.

In one embodiment, the amorphous chemical vapor deposition coating 107 is produced with the enclosed vessel being below the decomposition temperature of the fluid and is increased to above the decomposition temperature (for example, prior to, during, and/or after the introducing of the fluid). In a further embodiment, the decomposition temperature is greater than 200° C., greater than 300° C., greater than 350° C., greater than 370° C., greater than 380° C., greater than 390° C., greater than 400° C., greater than 410° C., greater than 420° C., greater than 430° C., greater than 440° C., greater than 450° C., greater than 500° C., between 300° C. and 450° C., between 350° C. and 450° C., between 380° C. and 450° C., between 300° C. and 500° C., between 400° C. and 500° C., or any suitable combination, sub-combination, range, or sub-range therein.

The fluid is cycled in a single cycle or multiple cycles, for example, with intermediate purges (for example, with inert gases, such as, nitrogen, helium, and/or argon). Suitable numbers of cycles include two cycles, three cycles, four cycles, five cycles, six cycles, seven cycles, eight cycles, nine cycles, ten cycles, eleven cycles, twelve cycles, thirteen cycles, fourteen cycles, fifteen cycles, sixteen cycles, or any suitable combination, sub-combination, range, or sub-range therein.

In one embodiment, the amorphous chemical vapor deposition coating 107 is produced with the partial pressures for the fluid being between 1 Torr and 10 Torr, 1 Torr and 5 Torr, 1 Torr and 3 Torr, 2 Torr and 3 Ton, 10 Torr and 150 Torr, between 10 Torr and 30 Torr, between 20 Torr and 40 Torr, between 30 Torr and 50 Torr, between 60 Torr and 80 Torr, between 50 Torr and 100 Torr, between 50 Torr and 150 Torr, between 100 Torr and 150 Torr, less than 150 Torr, less than 100 Torr, less than 50 Torr, less than 30 Torr, or any suitable combination, sub-combination, range, or sub-range therein.

In one embodiment, the amorphous chemical vapor deposition coating 107 is produced with the temperature and the pressure for being maintained for at least 10 minutes, at least 20 minutes, at least 30 minutes, at least 45 minutes, at least 1 hour, at least 2 hours, at least 3 hours, at least 4 hours, at least 5 hours, at least 7 hours, between 10 minutes and 1 hour, between 20 minutes and 45 minutes, between 4 and 10 hours, between 6 and 8 hours, or any suitable combination, sub-combination, range, or sub-range therein.

In one embodiment, the amorphous chemical vapor deposition coating 107 is post-cleaned, for example, in a turbulent manner and/or by repeating the treatment disclosed above. Additionally or alternatively, cleaning techniques include water deionized flushing with sonication, polyethylene pellets to soak up dust, CO₂ spray, and/or use of a chemical with good wetting/hydrophilicity (for example, isopropanol, ammonium hydroxide+water).

In one embodiment, the article 100 is exposed to an elevated temperature. Exemplary elevated temperatures include, but are not limited to, at least 1,050° C., at least 1,100° C., at least 1,200° C., or any suitable combination, sub-combination, range, or sub-range therein. Such conditions may be in inert environments and/or harsh conditions, such as, oxygen-rich environment, hydrochloric acid, metal halides, and/or alkaline conditions.

While the invention has been described with reference to one or more embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. In addition, all numerical values identified in the detailed description shall be interpreted as though the precise and approximate values are both expressly identified.

What is claimed is:

1. An article, comprising:
a molybdenum substrate; and
an amorphous chemical vapor deposition coating on the molybdenum substrate;
wherein the amorphous chemical vapor deposition coating includes silicon.

2. The article of claim 1, wherein the amorphous chemical vapor deposition coating and the molybdenum substrate have coefficients of thermal expansion that do not result in delamination when exposed to temperatures of greater than 1,200° C.

3. The article of claim 1, wherein the amorphous chemical vapor deposition coating includes a single continuous layer extending over a plurality of regions incapable of being coated by a line-of-site technique.

4. The article of claim 1, wherein the amorphous chemical vapor deposition coating includes nitrogen.

5. The article of claim 1, wherein the amorphous chemical vapor deposition coating includes nitrogen and is devoid of compositional ring structures.

6. The article of claim 1, wherein the amorphous chemical vapor deposition coating includes oxygen.

7. The article of claim 1, wherein the amorphous chemical vapor deposition coating includes a lattice of voids from thermal removal of carbonaceous material.

8. The article of claim 1, wherein the amorphous chemical vapor deposition coating includes oxygen at a greater concentration, by weight, than silicon.

9. The article of claim 1, wherein the amorphous chemical vapor deposition coating is substantially devoid of oxygen, substantially devoid being a concentration of less than 0.1%, by weight.

10. The article of claim 1, wherein the amorphous chemical vapor deposition coating is devoid of oxygen.

11. The article of claim 1, wherein the amorphous chemical vapor deposition coating is devoid of molybdenum.

12. The article of claim 1, wherein the molybdenum substrate has a composition, by weight, including greater than 50% molybdenum.

13. The article of claim 1, wherein the molybdenum substrate has a composition, by weight, including greater than 80% molybdenum.

14. The article of claim 1, wherein the molybdenum substrate has a composition, by weight, including greater than 90% molybdenum.

15. The article of claim 1, wherein the molybdenum substrate has a composition, by weight, including greater than 99% molybdenum.

16. The article of claim 1, wherein the article has been exposed to a temperature of at least 1,050° C.

17. The article of claim 1, wherein the article has been exposed to a temperature of at least 1,100° C.

18. The article of claim 1, wherein the article has been exposed to a temperature of at least 1,200° C.

19. A process of using an article, the process comprising:
providing the article, the article comprising a molybdenum substrate and an amorphous chemical vapor deposition coating on the molybdenum substrate, wherein the amorphous chemical vapor deposition coating includes silicon; and
exposing the article to temperatures of greater than 1,200 ° C.

20. A process of producing an article, the process comprising:
positioning a molybdenum substrate; and
applying an amorphous chemical vapor deposition coating on the molybdenum substrate through thermal chemical vapor deposition, wherein the amorphous chemical vapor deposition coating includes silicon.
